(19) United States
(12) Patent Application Publication
(10) Pub. No.: US 2008/0138966 A1
(43) Pub. Date: Jun. 12, 2008

(54) METHOD OF FABRICATING A DENSIFIED NANOPARTICLE THIN FILM WITH A SET OF OCCLUDED PORES

(76) Inventors: Elena V. Rogojina, Los Altos, CA (US); Francesco Lemmi, Sunnyvale, CA (US); Maxim Kelman, Mountain View, CA (US); Xuegeng Li, Sunnyvale, CA (US); Pingrong Yu, Sunnyvale, CA (US)

Correspondence Address: Foley & Lardner LLP, 150 East Gilman Street, Madison, WI, 53701-1497, US

(21) Appl. No.: 11/940,056

(22) Filed: Nov. 14, 2007

Related U.S. Application Data
(60) Provisional application No. 60/859,209, filed on Nov. 15, 2006.

(51) Int. Cl. H01L 21/208

(52) U.S. Cl. 438/502; 257/E21.115

(57) ABSTRACT

A method of fabricating a densified nanoparticle thin film with a set of occluded pores in a chamber is disclosed. The method includes positioning a substrate in the chamber; and depositing a nanoparticle ink, the nanoparticle ink including a set of Group IV semiconductor particles and a solvent. The method further includes heating the nanoparticle ink to a first temperature between about 30° C. and about 300° C., and for a first time period between about 5 minutes and about 60 minutes, wherein the solvent is substantially removed, and a porous compact with a set of pores is formed. The method also includes heating the porous compact to a second temperature between about 300° C. and about 900° C., and for a second time period of between about 5 minutes and about 15 minutes, and flowing a precursor gas into the chamber at a partial pressure between about 0.1 Torr and about 50 Torr, wherein the precursor gas substantially fills the set of pores, and wherein the densified nanoparticle film with the set of occluded pores is formed.

### CROSS-REFERENCE TO RELATED APPLICATIONS

This application claims the benefit of U.S. Provisional Patent Application Ser. No. 60/859,209 filed Nov. 15, 2006, the entire disclosure of which is incorporated by reference.

### FIELD OF DISCLOSURE

This disclosure relates in general to Group IV semiconductor thin films, and in particular to methods of fabricating a densified nanoparticle thin film with a set of occluded pores.

### BACKGROUND

The Group IV semiconductor materials enjoy wide acceptance as the materials of choice in a range of devices in numerous markets such as communications, computation, and energy. Currently, particular interest is aimed in the art at improvements in devices utilizing semiconductor thin film technologies due to the widely recognized disadvantages of chemical vapor deposition (CVD) technologies. For example, some of the drawbacks of the current CVD technologies in the fabrication of semiconductor thin films and devices include the slow deposition rates, which limit the cost-effective fabrication of a range of film thicknesses, the difficulty in accommodating large components, high processing temperatures, and the high production of chemical wastes.

In that regard, with the emergence of nanotechnology, there is in general growing interest in leveraging the advantages of these new materials in order to produce low-cost devices with designed functionality using high volume manufacturing on nontraditional substrates. It is therefore desirable to leverage the knowledge of Group IV semiconductor materials and at the same time exploit the advantages of Group IV semiconductor nanoparticles for producing novel thin films, which may be readily integrated into a number of devices. Particularly, Group IV nanoparticles in the range of between about 1.0 nm to about 100.0 nm may exhibit a number of unique electronic, magnetic, catalytic, physical, optoelectronic, and optical properties due to quantum confinement and surface energy effects.

With respect to thin films compositions utilizing nanoparticles, U.S. Pat. No. 6,878,871 describes photovoltaic devices having thin layer structures that include inorganic nanostructures, optionally dispersed in a conductive polymer binder. Similarly, U.S. Patent Application Publication No. 2003/0226498 describes semiconductor nanocrystal/conjugated polymer thin films, and U.S. Patent Application Publication No. 2004/0126582 describes materials comprising semiconductor particles embedded in an inorganic or organic matrix. Notably, these references focus on the use of Group II-VI or III-V nanostructures in thin layer structures, rather than thin films formed from Group IV nanostructures.

In U.S. Patent Application Publication No. 2006/0154036, composite sintered thin films of Group IV nanoparticles and hydrogenated amorphous Group IV materials are discussed. The Group IV nanoparticles are in the range 0.1 nm to 10 nm, in which the nanoparticles were passivated, typically using an organic passivation layer. In order to fabricate thin films from these passivated particles, the processing was performed at 400° C., where nanoparticles below 10 nm are used to lower the processing temperature. In this example, significant amounts of organic materials are present in the Group IV thin film layers, and the composites formed are substantially different than the well-accepted native Group IV semiconductor thin films.

U.S. Pat. No. 5,576,248 describes Group IV semiconductor thin films formed from nanocrystalline silicon and germanium of 1.0 nm to 100.0 nm in diameter, where the film thickness is not more than three to four particles deep, yielding film thickness of about 2.5 nm to about 20 nm. However, for many electronic and photoelectronic applications, Group IV semiconductor thin films of about 10 nm to 3 microns are desirable. The morphology and electronic characteristics of such thin films was not described.

Therefore, there is a need in the art for devices made from native Group IV semiconductor thin films, where the films are about 200 nm to 3 microns in thickness fabricated from Group IV semiconductor nanoparticles, which thin films are readily made using high volume processing methods.

### SUMMARY

The invention relates, in one embodiment, to a method of fabricating a densified nanoparticle thin film with a set of occluded pores in a chamber. The method includes positioning a substrate in the chamber; and depositing a nanoparticle ink, the nanoparticle ink including a set of Group IV semiconductor particles and a solvent. The method further includes heating the nanoparticle ink to a first temperature between about 30° C. and about 300° C., and for a first time period between about 5 minutes and about 60 minutes, wherein the solvent is substantially removed, and a porous compact with a set of pores is formed. The method also includes heating the porous compact to a second temperature between about 300° C. and about 900° C., and for a second time period of between about 5 minutes and about 15 minutes, and flowing a precursor gas into the chamber at a partial pressure between about 0.1 Torr and about 50 Torr, wherein the precursor gas substantially fills the set of pores, and wherein the densified nanoparticle film with the set of occluded pores is formed.

### BRIEF DESCRIPTION OF THE DRAWINGS

FIG. 1 is a schematic that depicts the formation of Group IV semiconductor thin films from a porous compact film in an inert environment, in accordance with the invention;

FIG. 2 depicts an embodiment of a thin film fabrication method using Group IV semiconductor nanoparticles, in accordance with the invention;

FIGS. 3A-3G depict an embodiment of a semiconductor device fabrication method using Group IV semiconductor nanoparticles, in accordance with the invention;

FIG. 4 is a cross-section of an embodiment of a tandem photoconductive structure fabricated using Group IV semiconductor nanoparticles, in accordance with the invention;

FIG. 5 is a cross-section of another embodiment of a tandem photoconductive structure fabricated using Group IV semiconductor nanoparticles, in accordance with the invention;

FIG. 6 is a cross-section of still another embodiment of a tandem photoconductive structure fabricated using Group IV semiconductor nanoparticles, in accordance with the invention;

FIG. 7 is a cross-section of an alternative embodiment of photoconductive structure fabricated using Group IV semiconductor nanoparticles, in accordance with the invention; and

FIG. 8 is a cross-section of an additional alternative embodiment of a tandem photoconductive structure fabricated using Group IV semiconductor nanoparticles, in accordance with the invention.

### DETAILED DESCRIPTION

Embodiments of thin films and devices formed from native Group IV semiconductor nanoparticles, and methods for making such thin films and devices are disclosed herein. The photoconductive thin films from which devices are formed result from coating substrates using dispersions of Group IV nanoparticles to form a porous compact. In order to fabricate a Group IV semiconductor thin film, either during the thermal fabrication of the porous compact or just subsequent to the formation of a densified thin film, Group IV semiconductor precursor gases are used to fill interstitial spaces in the films. In some embodiments of a method for fabrication, then, not only does the porous compact become densified, but the Group IV semiconductor precursor gas decomposes to fill or essentially fill the interstitial spaces in the porous compact with Group IV semiconductor material. In other embodiments, after densification, the Group IV precursor gas decomposes to fill or essentially fill the interstitial spaces in the thin film with Group IV semiconductor material. The effect of using such process methods utilizing a Group IV semiconductor precursor gas during Group IV semiconductor thin film fabrication from Group IV semiconductor nanoparticles is to create non-porous or essentially non-porous photoconductive Group IV semiconductor thin films thereby.

The embodiments of the disclosed photoconductive thin film devices fabricated from Group IV semiconductor nanoparticle starting materials evolved from the inventors' observations that by keeping embodiments of the native Group IV semiconductor nanoparticles in an inert environment from the moment they are formed through the formation of Group IV semiconductor thin films, that such thin films so produced have properties characteristic of native bulk semiconductor materials. In that regard, the photoconductive devices that are then fabricated from such thin films are formed from materials for which the electrical, spectral absorbance and photoconductive properties are well characterized. This is in contrast, for example, to the use of modified Group IV semiconductor nanoparticles, which modifications generally use organic species to stabilize the reactive particles, or mix the nanoparticles with organic modifiers, or both. In some such modifications, the Group IV nanoparticle materials are significantly oxidized. The use of these types of nanoparticle materials produces hybrid thin films, which hybrid thin films do not have as yet the same desirable properties as traditional Group IV semiconductor materials.

As used herein, the term “Group IV semiconductor nanoparticle” generally refers to hydrogen terminated Group IV semiconductor nanoparticles having an average diameter between about 1.0 nm to 100.0 nm, and composed of silicon, germanium, and alpha-tin, or combinations thereof. As will be discussed subsequently, some embodiments of thin film devices utilize doped Group IV semiconductor nanoparticles. With respect to shape, embodiments of Group IV semiconductor nanoparticles include elongated particle shapes, such as nanowires, or irregular shapes, in addition to more regular shapes, such as spherical, hexagonal, and cubic nanoparticles, and mixtures thereof. Additionally, the nanoparticles may be single-crystalline, polycrystalline, or amorphous in nature. As such, a variety of types of Group IV semiconductor nanoparticle materials may be created by varying the attributes of composition, size, shape, and crystallinity of Group IV semiconductor nanoparticles. Exemplary types of Group IV semiconductor nanoparticle materials are yielded by variations including, but not limited by: 1.) single or mixed elemental composition; including alloys, core/shell structures, doped nanoparticles, and combinations thereof 2.) single or mixed shapes and sizes, and combinations thereof, and 3.) single form of crystallinity or a range or mixture of crystallinity, and combinations thereof.

Regarding the terminology of the art for Group IV semiconductor thin film materials, the term “amorphous” is generally defined as noncrystalline material lacking long-range periodic ordering, while the term “polycrystalline” is generally defined as a material composed of crystallite grains of different crystallographic orientation, where the amorphous state is either absent or minimized (e.g. within the grain boundary and having an atomic monolayer in thickness). With respect to the term “microcrystalline”, in some current definitions, this represents a thin film having properties between that of amorphous and polycrystalline, where the crystal volume fraction may range between a few percent to about 90%. In that regard, on the upper end of such a definition, there is arguably a continuum between that which is microcrystalline and polycrystalline. For the purpose of what is described herein, “microcrystalline” is a thin film in which microcrystallites are embedded in an amorphous matrix, and “polycrystalline” is not constrained by crystallite size, but rather a thin film having properties reflective of the highly crystalline nature.

The Group IV semiconductor nanoparticles may be made according to any suitable method, several of which are known, provided they are initially formed in an environment that is substantially inert, and substantially oxygen-free. As used herein, “inert” is not limited to only substantially oxygen-free. It is recognized that other fluids (i.e., gases, solvents, and solutions) may react in such a way that they negatively affect the electrical and photoconductive properties of Group IV semiconductor nanoparticles. Additionally, the terms “substantially oxygen-free” in reference to environments, solvents, or solutions refer to environments, solvents, or solutions wherein the oxygen content has been substantially reduced to produce Group IV semiconductor thin films having no more than 10¹⁷ to 10¹⁹ oxygen per cubic centimeter of Group IV semiconductor thin film. For example, it is contemplated that plasma phase preparation of hydrogen-terminated Group IV semiconductor nanoparticles is done in an inert, substantially oxygen-free environment. As such, plasma phase methods produce nanoparticle materials of the quality suitable for making embodiments of Group IV semiconductor thin film devices. For example, one plasma phase method, in which the particles are formed in an inert, substantially oxygen-free environment, is disclosed in U.S. patent application Ser. No. 11/155,340, filed Jun. 17, 2005; the entirety of which is incorporated herein by reference.

It is contemplated that embodiments of doped Group IV semiconductor nanoparticles can be utilized to fabricate doped Group IV semiconductor thin film devices. In that regard, during plasma phase preparation, dopants can be introduced in to gas phase during the formation and growth of Group IV semiconductor nanoparticles. For example, n-type Group IV semiconductor nanoparticles may be prepared using a plasma phase method in the presence of well-known gases such as phosphorous oxychloride, phosphine, or arsine. Alternatively, p-type semiconductor nanoparticles may be prepared in the presence of boron difluoride, trimethyl borane, or diborane. For core/shell Group IV semiconductor nanoparticles, the dopant may be in the core or the shell or both the core and the shell.

After the preparation of quality Group IV semiconductor nanoparticles in an inert, substantially oxygen-free environment, the particles are formulated as dispersions or inks in an inert, substantially oxygen-free environment, so that they can be deposited on a solid support. In terms of preparation of the dispersions, the use of particle dispersal methods such as sonication, high shear mixers, and high pressure/high shear homogenizers are contemplated for use to facilitate dispersion of the particles in a selected solvent or mixture of solvents. For example, inert dispersion solvents contemplated for use include, but are not limited to chloroform, tetrachloroethane, chlorobenzene, xylenes, mesitylene, diethylbenzene, 1,3,5 triethylbenzene (1,3,5 TEB), silanes, and combinations thereof.

Various embodiments of Group IV semiconductor nanoparticle inks can be formulated by the selective blending of different types of Group IV semiconductor nanoparticles. For example, varying the packing density of Group IV semiconductor nanoparticles in a deposited thin layer is desirable for forming a variety of embodiments of Group IV photoconductive thin films. In that regard, Group IV semiconductor nanoparticle inks can be prepared in which various sizes of monodispersed Group IV semiconductor nanoparticles are specifically blended to a controlled level of polydispersity for a targeted nanoparticle packing. Further, Group IV semiconductor nanoparticle inks can be prepared in which various sizes, as well as shapes are blended in a controlled fashion to control the packing density.

Still another example of what may achieved through the selective formulation of Group IV semiconductor nanoparticle inks by blending doped and undoped Group IV semiconductor nanoparticles. For example, various embodiments of Group IV semiconductor nanoparticle inks can be prepared in which the dopant level for a specific thin layer of a targeted device design is formulated by blending doped and undoped Group IV semiconductor nanoparticles to achieve the requirements for that layer. In still another example are embodiments of Group IV semiconductor nanoparticle inks that may compensate for defects in embodiments of Group IV photoconductive thin films. For example, it is known that in an intrinsic silicon thin film, oxygen may act to create undesirable energy levels. To compensate for this, low levels of p-type dopants, such as boron difluoride, trimethyl borane, or diborane, may be used to compensate for the presence of low levels of oxygen. By using Group IV semiconductor nanoparticles to formulate embodiments of inks, such low levels of p-type dopants may be readily introduced in embodiments of blends of the appropriate amount of p-doped Group IV semiconductor nanoparticles with various types of undoped Group IV semiconductor nanoparticles.

Other embodiments of Group IV semiconductor nanoparticle inks can be formulated that adjust the band gap of embodiments of Group IV photoconductive thin films. For example, the band gap of silicon is about 1.1 eV, while the band gap of germanium is about 0.7 eV, and for alpha-tin is about 0.05 eV. Therefore, formulations of Group IV semiconductor nanoparticle inks may be selectively formulated so that embodiments of Group IV photoconductive thin films may have photon adsorption across a wider range of the electromagnetic spectrum.

Still other embodiments of inks can be formulated from alloys and core/shell Group IV semiconductor nanoparticles. For example, it is contemplated that silicon carbide semiconductor nanoparticles are useful for in the formation of a variety of semiconductor thin films and semiconductor devices. In other embodiments, alloys of silicon and germanium are contemplated. Such alloys may be made as discrete alloy nanoparticles, or may be made as core/shell nanoparticles.

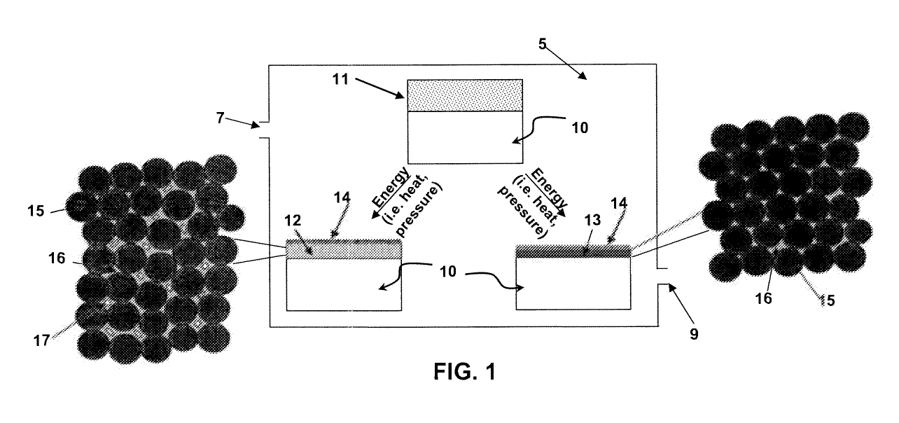

After the preparation of an ink, a thin film of Group IV semiconductor nanoparticles is deposited onto a substrate, followed by fabrication into a Group IV semiconductor thin film. This is shown schematically in FIG. 1, which is a rendering for the purpose of highlighting concepts, and is not meant as an actual representation of the film morphology of embodiments of Group IV semiconductor thin films disclosed herein. It is contemplated that a variety of spraying, dipping, brushing, casting, and printing technologies could be used for taking formulations of Group IV semiconductor inks and depositing a porous compact 11 on substrate 10. From the porous compact 11, two embodiments of thin films 12,13 are shown, which thin films 12,13 are fabricated in an inert environment in a fabrication chamber or compartment 5. Additionally, as previously mentioned, during the fabrication of embodiments of Group IV semiconductor thin films, Group IV semiconductor precursor gases are introduced into the fabrication chamber or compartment 5 through inlet 7, and exhausted through outlet 9.

The substrate 10 may be selected from a variety of materials, such as silicon dioxide-based materials, either with or without a thin barrier layer of a material on the surface in contact with the porous compact 11. The silicon dioxide-based substrates include, but are not limited by, quartz, and glasses, such as soda lime and borosilicate glasses. The deposited thin barrier layer may be selected from conductive materials, such as molybdenum, titanium, nickel, and platinum. Alternatively, the deposited barrier film layer may be selected from dielectric materials, such as silicon nitride or alumina. For some embodiments of Group IV semiconductor thin films, stainless steel is the substrate of choice. Finally, for other embodiments of Group IV semiconductor thin films, the substrate may be selected from heat-durable polymers, for example, such as polyimides and aromatic fluorene-containing polyarylates, which are examples of polymers having glass transition temperatures above about 300° C.

In another aspect of what is depicted in FIG. 1, different fabrication conditions used in the fabrication of a thin film from a porous compact may produce different embodiments of thin films. As previously mentioned, in some embodiments, at the target fabrication temperature, not only does the porous compact become densified, but the Group IV semiconductor precursor gas decomposes to fill or essentially fill the interstitial spaces between packed particles with Group IV semiconductor material. In other embodiments, the process step using the Group IV semiconductor precursor gas to fill or essentially fill the interstitial spaces with Group IV semiconductor material may be done after the densified thin film is formed, but before it is removed from the inert environment. The impact of the use of the precursor gas is to create non-porous or essentially non-porous photoconductive Group IV semiconductor thin films. For example, in FIG. 1, from a porous compact 11, when subjected to certain conditions of heat and optionally pressure in the presence of precursor gas, may form embodiments of a photoconductive thin films 12,13. In this depiction, one embodiment of a thin film 12, which is more compact than the porous compact 11 is shown. In the depicted exploded view of thin film 12, particles 15 have interstitial spaces 16 essentially filled with Group IV semiconductor material formed from the decomposition of the precursor gas. In densified film 12 pores 17 may be retained that have become occluded, such that they are no longer in fluid communication with other pores or the external environment. Additionally, as will be discussed in more detail, an optional step in the fabrication of embodiments of photoconductive thin film 12 may be the deposition of a thin layer of Group IV semiconductor material 14 on the top of thin film 12 using the precursor gas, which may act to seal thin film 12.

In other embodiments of thin films, under different conditions for example, such as the type of ink used, the method of deposition of the ink, the partial pressure of the precursor gas, and altering the fabrication conditions of time, temperature and optionally pressure, a more densified thin film may be fabricated. A more densified thin film is depicted in the rendering of thin film 13. In thin film 13, the interstitial spaces 16 are filled or essentially filled with Group IV semiconductor material formed from the decomposition of the precursor gas, eliminating or essentially eliminating the pore structure thereby.

Therefore in embodiments of the thin films disclosed herein, the fabrication may significantly fill the interstitial spaces, and produce occluded pores that are not in fluid communication with other pores or the external environment, while in still other embodiments, the conditions may be selected so that interstitial spaces are filled or essentially filled, and the pores are either greatly reduced or eliminated. Embodiments of thin films so produced are a continuum of Group IV semiconductor materials, and as such have the characteristic properties of such materials. By varying the nature of the porous compact in terms of the degree of porosity or compactness, as well as the fabrication parameters, materials ranging from polycrystalline to microcrystalline may be readily formed. Additionally, an optional step in which precursor gas is used to deposit a thin layer of Group IV semiconductor material on the top of a photoconductive thin film formed using Group IV semiconductor nanoparticles is disclosed. Such a thin layer may be useful in sealing such a photoconductive thin film, and protecting the thin film integrity thereby.

The fabrication steps are done in an inert, substantially oxygen free environment, using temperatures between about 300° C. to about 900° C. Heat sources contemplated for use include conventional contact thermal sources, such as resistive heaters, as well as radiative heat sources. Such radiative sources include, for example lamps, lasers, microwave processing equipment, and plasmas. More specifically, tungsten-halogen and continuous arc lamps are exemplary of radiative lamp sources. Additionally, lasers operating in the wavelength range between about 0.3 micron to about 10 micron, and microwave processing equipment operating in even longer wavelength ranges are matched to the fabrication requirements of embodiments of Group IV semiconductor thin films described herein. These types of apparatuses have the wavelengths for the effective penetration of the targeted film thicknesses, as well as the power requirements for fabrication of such thin film devices.

With respect to factors affecting the fabrication of a deposited Group IV nanoparticle thin film into a densified thin film, the time required varies as an inverse function in relation to the fabrication temperature. For example, if the fabrication temperature is about 800° C., then for various embodiments of Group IV photoconductive thin films, the fabrication time may be, for example, between about 5 minutes to about 15 minutes. However, if the fabrication temperature is about 400° C., then for various embodiments of Group IV photoconductive thin films, the fabrication temperature may be between about, for example, 1 hour to about 10 hours. The fabrication process may also optionally include the use of pressure of up to about 7000 psig. The fabrication of Group IV semiconductor thin films from Group IV semiconductor nanoparticle materials has been described in US Provisional Application; App. Ser. No. 60/842,818, with a filing date of Sep. 7, 2006, and entitled, “Semiconductor Thin Films Formed from Group IV Nanoparticles”. The entirety of this application is incorporated by reference.

Group IV semiconductor precursor gases may be selected from for example, but not limited by, silane, disilane, germane, digermane, any of their halide analogs, and combinations thereof. Additionally, mixtures of gases to produce semiconductor alloys of Group IV semiconductor materials are contemplated. For example, methane and silane may be used in combination to produce silicon carbide The desired characteristic of the precursor gas is that it must be readily decomposed into Group IV semiconductor material well below the melting point of the corresponding bulk material; that is between about 300° C. to about 900° C. It should be noted that the precursor gas is typically mixed with an inert gas, for example, such as nitrogen and hydrogen, and noble gases for example, such as argon and helium. In some embodiments of methods for filling interstitial spaces with Group IV semiconductor material, the composition of the precursor gas in the inert gas may vary from 1%, to 100% precursor gas, while in other embodiments, the composition of precursor gas may vary from about 2% to about 20%. In a fabrication chamber, the partial pressure of the precursor gas or precursor gas composition is maintained at between about 0.1 Torr to about 50 Torr. Though the range of processing in which thermal decomposition of the precursor gas during fabrication of a Group IV semiconductor thin film may be between about 300° C. to about 900° C., for many gases with lower decomposition temperatures the range of about 500° C. to about 700° C. is adequate for promoting decomposition. In addition to heat, the precursor gases may also be decomposed using sources such as lamps, for example, tungsten-halogen lamps and continuous arc lamps, lasers operating in the wavelength range between about 0.3 micron to about 10 micron, microwave processing equipment, and plasmas. In that regard, the process of filling the interstitial spaces in a thin film by decomposing precursor gases is compatible with the previously discussed methods used for fabricating photoconductive thin films from films of deposited Group IV semiconductor nanoparticles.

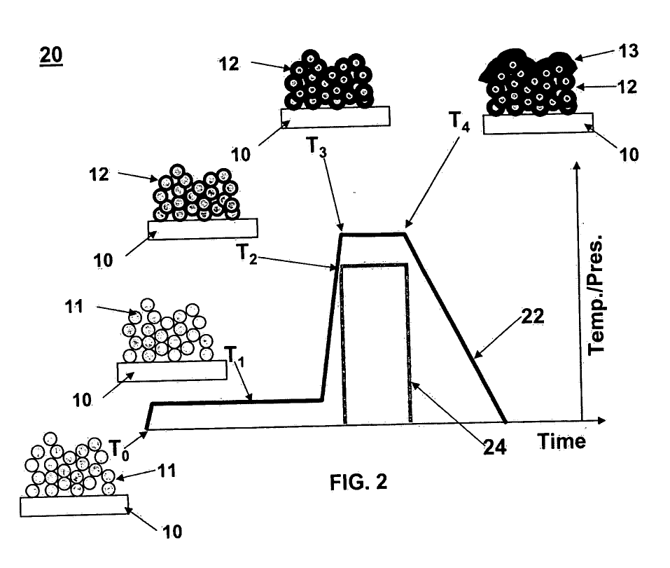

In FIG. 2, an example of an embodiment of a thin film fabrication method 20 is depicted, which is a rendering for the purpose of highlighting concepts, and is not meant as an actual representation of the film morphology of embodiments of Group IV semiconductor thin films disclosed herein. Additionally, all process steps of thin film fabrication method 20 depicted in FIG. 2 are carried out under inert conditions as described for FIG. 1.

In the exemplary embodiment of thin film fabrication method 20 of FIG. 2, an embodiment of a thermal ramp profile 22, and an embodiment of a precursor gas profile 24 are indicated. At the initial time, T₀, porous compact 11 is deposited on substrate 10, and is ready for fabrication. In the second process step, at time interval including T₁, the sample is conditioned before the thermal processing of the porous compact to fabricate a photoconductive thin film 12. Such a conditioning step may be useful for driving off volatile chemical species, such as solvent, as well as assisting in making the porous compact 11 more mechanically stable. Such a step may be done for about 5 minutes to about one hour, and between the temperatures of about 30° C. to about 300° C. in an inert environment, for example, such as in the presence of an inert gas, or in vacuo. After the conditioning step, the temperature is ramped towards a targeted fabrication temperature of between 300° C. to about 900° C. Before reaching the targeted fabrication temperature, at a time T₂, the precursor gas is allowed to flow into the fabrication chamber to a targeted partial pressure, of between about 0.1 Torr to about 50 Torr. As indicated for an exemplary embodiment of thin film fabrication method 20, the time for introducing the precursor gas may be done at a temperature below the targeted thermal processing temperature, but above the temperature at which the precursor gas will decompose. In this regard, the Group IV semiconductor material so deposited will be deposited in the initial stages of densification of the thin film 12, as shown in FIG. 2 at time T₂. In alternative embodiments of thin film fabrication method 20, the onset of the introduction of the precursor gas may occur at various times during the device fabrication. For example, in some embodiments of device fabrication method 20, the precursor gas may be introduced before thermal processing is initiated in order to fill the interstitial spaces of the porous compact, while in other embodiments the precursor gas may be introduced in the interval of the conditioning portion of the ramp. In still other embodiments, precursor gas may be introduced in the thermal processing step after densification has progressed. In still other embodiments of thin film fabrication method 20, the introduction of the precursor gas may occur after the fabrication of the thin film 12 has been completed. The thermal processing for the fabrication of thin film 12 is held for an interval of time, which is depicted in FIG. 2 between T₃ and T₄. For the exemplary embodiment of thin film fabrication 20 depicted in FIG. 2, in the interval T₃ and T₄ in which film densification is occurring, precursor gas is being continually deposited and decomposed, filling or essentially filling the interstitial spaces thereby. Finally, when the interstitial spaces are filled or essentially filled, the conditions may be chosen so that optionally, a capping layer 13 of Group IV semiconductor material may be formed on top of the fabricated Group IV semiconductor thin film 12. The thickness of layer 13 may be up to about 500 nm.

A formulation of a 20 mg ml dispersion of silicon nanoparticles of about 8.0 nm in diameter was prepared in a solvent mixture of chloroform/chlorobenzene (4:1; v/v). A quartz substrate (1″×1″) with a 100 nm layer of molybdenum was covered with a sufficient volume of the silicon nanoparticle dispersion, and a porous compact was formed using spin casting (500 rpm for 1 minute). The porous compact was then subjected to a conditioning step of 100° C. for 30 minutes in vacuo at about 10 mTorr. A thermal ramp of between about 2° C./sec to about 3° C./sec was applied to the fabrication chamber to a final setting of 575° C. for 15 minutes. At about 500° C., precursor gas comprising a mixture of 90% argon and 10% silane (v/v) was introduced into the fabrication chamber at a total gas pressure of 10 Torr, and was held at that pressure for the duration of thermal processing to form a silicon thin film. An SEM was taken of a cross-section of a thin film, evenly distributed on the molybdenum layer, which is on quartz substrate. A control was run using the same fabrication method used for the thin film, except that the gas used was 100% argon. In comparison to the control, the thin film appeared to be a more densified film than the control. For the plan view of the thin film which was subjected to the precursor gas as described, there was an apparent top layer of polycrystalline silicon, which was clearly missing in the control. In that regard, the thin film fabricated using an embodiment of a method for making a thin film 20 appeared not only more densified from the deposition of silicon material within the thin film body, but sealed by a thin layer of polycrystalline silicon, as well. Such features were absent in the control.

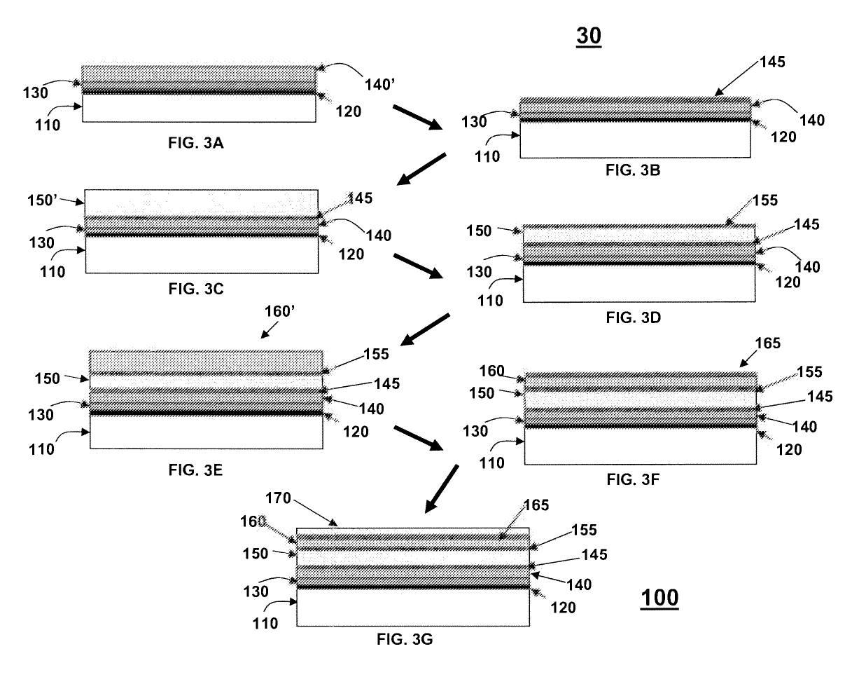

In FIGS. 3A-3G, an embodiment of device fabrication method 30 for the fabrication of a complete p/i/n device 100 from Group IV semiconductor nanoparticles is depicted. All process steps for device 100 fabrication depicted in FIGS. 3A-3G are carried out under conditions as described for FIG. 1 using a precursor gas either during or just subsequent to the fabrication of embodiments of device 100. In FIG. 3A, after an optional insulating layer 120 and the first electrode 130 have been deposited, a first Group IV nanoparticle film layer 140′ of the device 100 is deposited. The first electrode 130 is selected from conductive materials, such as, for example, aluminum, molybdenum, chromium, titanium, nickel, and platinum. For various embodiments of photoconductive devices contemplated, the first electrode 130 is between about 10 nm to about 1000 nm in thickness. Optionally, an insulating layer 120 may be deposited on the substrate 110 before the first electrode 130 is deposited. Such an optional layer is useful when the substrate is a dielectric substrate, since it protects the subsequently fabricated Group IV semiconductor thin films from contaminants that may diffuse from the substrate into the Group IV semiconductor thin film during fabrication. When using a conductive substrate, the insulating layer 120 not only protects Group IV semiconductor thin films from contaminants that may diffuse from the substrate, but is required to prevent shorting. Additionally, an insulating layer 120 may be used to planarize an uneven surface of a substrate. Finally, the insulating layer may be thermally insulating to protect the substrate from stress during some types of processing, for example, when using lasers. The insulating layer 120 is selected from dielectric materials such as, for example, but not limited by, silicon nitride and alumina. For various embodiments of photoconductive devices contemplated the insulating layer 120 is about 50 nm to about 500 nm in thickness.

In some embodiments of device fabrication method 30, the first deposited crystalline Group IV semiconductor nanoparticle layer 140′ is deposited using an embodiment of a Group IV semiconductor n-doped nanoparticle ink. In such embodiments, the n-doped layer 140′ is then processed in an inert, substantially oxygen free environment at a selected temperature in the presence of a precursor gas for a targeted duration of time, and optionally using pressure, to form an n-doped photoconductive thin-film layer 140, as shown in FIG. 3B. In another embodiment of device fabrication method 30, nanoparticle layer 140′ is deposited using an embodiment of a Group IV semiconductor nanoparticle ink, and during the processing of the porous compact 140′ to fabricate the n-doped layer 140 shown in FIG. 3B, precursor gas, including a dopant gas such as phosphine, arsine, and phosphorous oxychloride may be used for the in situ doping of thin film 140. In still another embodiment of device fabrication method 30, both doped particles and in situ doping during the filling interstitial spaces with Group IV semiconductor material with decomposed precursor gas is done. In all the aforementioned embodiments of device fabrication method 30 the fabrication and the filling of the interstitial spaces are done during the fabrication of thin film 140.

In still other embodiments of device fabrication method 30, filling of the interstitial spaces is done subsequent to the fabrication of the Group IV semiconductor thin film 140. For example, Group IV semiconductor film 140 is formed using either undoped or n-doped Group IV semiconductor nanoparticles in an inert, substantially oxygen free environment. Then, after the formation of thin film 140, while still in an inert, substantially oxygen free environment any interstitial spaces in fluid communication with the external environment are filled with precursor gas or precursor gas including dopant gas such as phosphine, arsine, and phosphorous oxychloride, which decomposes to fill or essentially fill the interstitial spaces. For all embodiments, optionally, a capping layer 145 of Group IV semiconductor material may be deposited.

The second deposited crystalline Group IV semiconductor nanoparticle layer 150′ shown in FIG. 3C is an intrinsic layer. Embodiments of the intrinsic layer 150′ may be formed from an ink formulated using undoped amorphous, polycrystalline, or crystalline silicon nanoparticles, or combinations thereof, and is between about 0.5 microns to about 3.0 microns in thickness. Other embodiments of intrinsic layer 150′ may be formed using a silicon nanoparticle ink specifically formulated using a blend of silicon nanoparticles, and an appropriate amount of p-doped silicon nanoparticles, so as to compensate for contaminants, such as oxygen, which may then act to create undesirable energy levels. In such embodiments, the intrinsic layer 150′ is then processed in an inert, substantially oxygen free environment at a selected temperature in the presence of a precursor gas for a targeted duration of time, and optionally using pressure, to form an intrinsic photoconductive thin-film layer 150, as shown in FIG. 3D.

Alternatively, in still other embodiments of device fabrication method 30, the filling of the interstitial spaces is done subsequent to the fabrication of the Group IV semiconductor thin film 150. For example, Group IV semiconductor film 150 is formed using either undoped or an appropriate amount of p-doped particles mixed with undoped Group IV semiconductor nanoparticles in an inert, substantially oxygen free environment. Then, after the formation of thin film 150, while still in an inert, substantially oxygen free environment, any interstitial spaces in fluid communication with the external environment are filled with precursor gas, which decomposes to fill or essentially fill the interstitial spaces. As for the n-doped layer 140, for all embodiments of intrinsic thin film 150, optionally, a thin capping layer 155 of Group IV semiconductor material may be deposited.

In FIG. 3E, after the formation of an intrinsic photoconductive Group IV semiconductor thin film 150, the p-doped nanoparticle thin film layer 160′ is deposited using an embodiment of a Group IV semiconductor p-doped nanoparticle ink and then is processed in an inert, substantially oxygen free environment at a selected temperature in the presence of a precursor gas for a targeted duration of time, and optionally using pressure, to form an p-doped photoconductive thin-film layer 160, as shown in FIG. 3F. In another embodiment of device fabrication method 30, nanoparticle layer 160′ is deposited using an embodiment of a Group IV semiconductor nanoparticle ink, and during the processing of the porous compact 160′ to form the p-doped layer 160 shown in FIG. 3F, precursor gas, including a dopant gas such as boron difluoride, trimethyl borane, or diborane may be used for the in situ doping of thin film 160. Alternatively, in still another embodiment of device fabrication method 30, both doped particles and in situ doping during the filling interstitial spaces with Group IV semiconductor material with decomposed precursor gas is done. As previously mentioned for the n-doped and intrinsic layers, in other embodiments of device fabrication method 30, the filling of the interstitial spaces is done subsequent to the fabrication of the Group IV semiconductor thin film 160. For example, Group IV semiconductor film 160 is formed using either undoped or p-doped Group IV semiconductor nanoparticles in an inert, substantially oxygen free environment. Then, after the formation of thin film 160, while still in an inert, substantially oxygen free environment any interstitial spaces in fluid communication with the external environment are filled with precursor gas or precursor gas including dopant gas such as boron difluoride, trimethyl borane, or diborane, which decomposes to fill or essentially fill the interstitial spaces. As previously discussed for both the n-doped thin film 140 and intrinsic film 150, p-doped thin film 160 may be optionally sealed with the deposition of a thin capping layer 165. Finally, a transparent conductive oxide (TCO) layer 170 is deposited on the p-doped layer to complete the fabrication of device 100 of FIG. 3G. As one of ordinary skill in the art is apprised, though the organization of device 100 is shown in this example as p/i/n, the layers can be organized as n/i/p.

Moreover, in one embodiment of device fabrication method 30, sequential strata are deposited using the same type of Group IV semiconductor nanoparticle ink in order to fabricate a single thin film layer, such as the n-doped thin film layer 140, the intrinsic layer 150, or the p-doped thin film layer 160 of device 100 of FIG. 3G. Such a method may be effective in repairing mechanical defects, such as pin holes or cracks, formed in a first fabricated stratum by the subsequent deposition of a second stratum of a Group IV semiconductor nanoparticle ink, followed by the stepwise fabrication of the strata. There is a low probability of defects aligning during such a stepwise fabrication of a single layer, thereby serving as a useful process for increasing yield. The ease of application of Group IV nanoparticle inks, providing deposition of a range of thicknesses of Group IV nanoparticle thin films, provides for ready integration of such a process step during Group IV photoconductive thin film fabrication. In embodiments of device fabrication method 30 utilizing the stepwise deposition of strata to build a film layer, the use of the precursor gas to fill the interstitial spaces could be done as a last layer is being deposited during the fabrication of a photoconductive thin film layer, or after a porous compact has been processed to fabricate a photoconductive thin film layer.

Other considerations for greatly reducing or eliminating defects during the processing of Group IV semiconductor nanoparticle thin films to fabricate a photoconductive Group IV semiconductor thin films include: 1.) controlling the processing parameters of temperature and pressure, 2.) optimizing the film thicknesses, and 3.) the selection of the type of Group IV nanoparticle material for a targeted photoconductive Group IV semiconductor thin film.

Controlling the process parameters of temperature and pressure, and optimizing film thickness ensure that structural defects will be minimized or eliminated during processing in order to maximize the yield of functional devices. Generally, it is desirable to select the minimal processing temperature and time for achieving the conversion of the Group IV semiconductor nanoparticle thin films to Group IV semiconductor nanoparticle thin films. This not only has an impact on process costs, but moreover acts to minimize the redistribution of dopant molecules during processing, and may reduce stress defects, as well. In that regard, the use of a ramp rate of the temperature and optionally the pressure conditions may also ensure that the Group IV semiconductor nanoparticle thin films experience no initial untoward thermal or baric stress. Additionally, the appropriate ramp rates of processing parameters ensure evenness of processing conditions throughout the processing apparatus, and hence throughout the devices being processed, also decreasing the probability of inducing stress in devices during processing thereby.

Film thickness is optimized to target Group IV nanoparticle film thicknesses that will result in Group IV photoconductive thin films of sufficient thickness to provide the targeted function, but as thin as possible to achieve that result in order to minimize the formation of structural defects during processing.

Embodiments of nanoparticle thin films having specific functionality may be derived from variations of the nanoparticle material crystallinity, composition, size, and shape. More specifically, various embodiments of Group IV semiconductor thin film devices can be fabricated by varying the particle sizes and shapes to adjust the packing density of the deposited Group IV semiconductor nanoparticle thin film, as well as varying the particle composition and size to adjust the fabrication temperature of such deposited thin films.

As one of ordinary skill in the art is apprised, photoconductive devices generally consist of multiple layers of semiconductor materials, as shown for device 100 in FIG. 3G. However, it should be noted that a single layer device fabricated from single type of Group IV semiconductor nanoparticle material has utility for devices not requiring high efficiency, and hence not high power. Such devices include, but are not limited by consumer devices, such as watches, calculators, and phones, as well as devices such as photodetectors.

In that regard, embodiments of devices comprising a single layer of a Group IV semiconductor thin film could be fabricated in a fashion similar to that of device 100 shown in FIG. 3G. In such embodiments, a single layer of a variety of types of crystalline Group IV semiconductor nanoparticles could be used to produce a crystalline thin film layer between the first electrode 130 and the second electrode 170. For example, nanoparticles of crystalline silicon, germanium, and alpha-tin, or combinations thereof could be used to form a single thin film layer, where for various embodiments, the particle sizes and shapes could be varied.

In a similar fashion, other embodiments of a single layer of a Group IV semiconductor material comprising amorphous Group IV semiconductor nanoparticles could be used between the first electrode 130 and the second electrode 170. Still other embodiments of single-layer Group IV semiconductor thin film devices can be fabricated using combinations of types of crystalline and amorphous Group IV semiconductor nanoparticle materials, in which microcrystallite Group IV semiconductor materials are embedded in amorphous Group IV semiconductor materials. For example, nanoparticles of crystalline silicon, germanium, and alpha-tin, or combinations thereof could be mixed with amorphous silicon, germanium, and alpha-tin, or combinations thereof, and processed to form a single microcrystalline thin film layer. As has been described for the other embodiments of single-junction Group IV semiconductor thin film devices, various embodiments of Group IV semiconductor thin film devices can be fabricated by varying the particle sizes and shapes to impact the packing of the deposited Group IV semiconductor nanoparticle thin film, as well as varying the particle composition and size to impact fabrication temperature of such deposited thin films. For embodiments of Group IV single layer photoconductive devices, the electric field which develops in such the devices due to the work functions of the electrode materials in contact with the Group IV photoconductive layer, or from heterojunctions formed in the layer using Group IV semiconductor nanoparticle blends. Embodiments of a single layer of Group IV semiconductor nanoparticles, which is fabricated to a photoconductive Group IV thin film could be fabricated as previously described for the thin film fabrication method 20 depicted in FIG. 2, and may optionally include a capping layer, such as 145, 155, and 165. After fabrication of a single Group IV photoconductive thin film, a transparent conductive oxide (TCO), such as layer 170 of FIG. 3G, is deposited.

In addition to a device having a single thin film layer, single junction devices comprised of two layers are also contemplated. In FIG. 3G, for embodiments of device 100 fabricated without intrinsic layer 150, then such a device would be a singe junction p/n photoconductive thin film fabricated with a first n-doped Group IV semiconductor photoconductive thin film 140 and a second p-doped photoconductive Group IV semiconductor thin film 160. Alternatively, in another embodiment, a singe junction p/n photoconductive thin film may be fabricated with a first p-doped Group IV semiconductor photoconductive thin film 160 and a second n-doped photoconductive Group IV semiconductor thin film 140. The two thin films together are about between 0.1 microns to about 10 microns in thickness for many applications, but may be as thick as up to 100 microns for others. For various embodiments of device 100 of FIG. 3G, the n-doped and p-doped photoconductive Group IV semiconductor layers individually may vary depending on the application. For example, in some embodiments, 140 and 160 may be the same thickness, while in other embodiments the p-doped layer 160 may be between about 10% to about 20% of the thickness of the n-doped layer 140, while in still other embodiments, the n-doped layer 140 may be between about 10% to about 20% of the thickness of the p-doped layer 160. As previously discussed, the n-doped layer and p-doped layer may optionally have a capping layer, such as 145, 155, and 165 of FIG. 3G. Finally, after the processing to form the p/n junction, a transparent conductive oxide (TCO), such as layer 170 of FIG. 3G, is deposited on the p-doped layer.

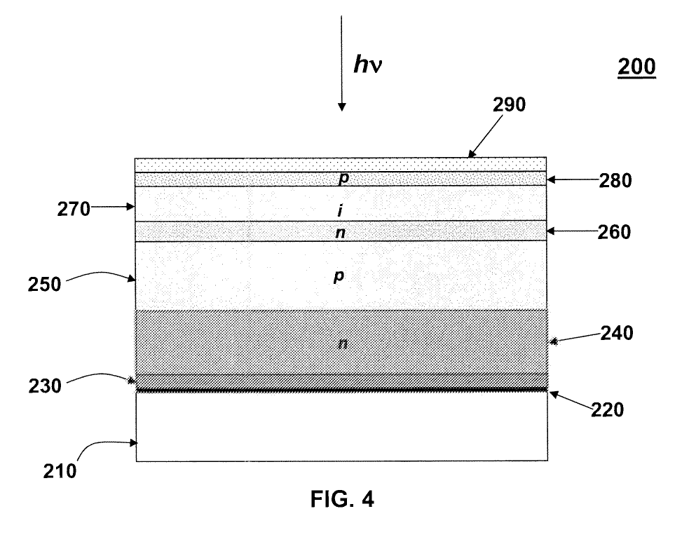

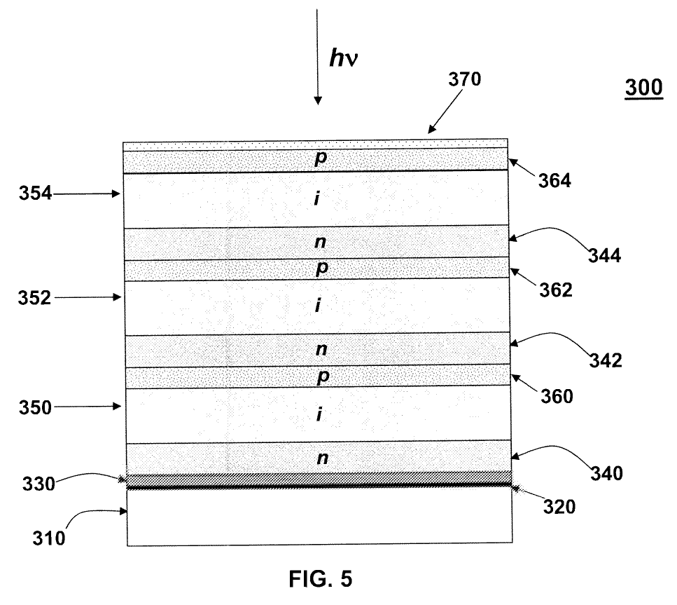

Using embodiments of process method 30, tandem devices having greater complexity may be fabricated. In FIG. 4, an embodiment of a tandem device is depicted that may be fabricated using embodiments of fabrication method 30. For photoconductive device 200 of FIG. 3, considerations for substrate 210, insulating layer 220, and first electrode 230, for photoconductive device 200 are the same as for that given for photoconductive device 100 shown in FIG. 3G. FIG. 4 depicts a tandem device that combines a single junction p/i/n device 100 of FIG. 3G, in combination with a single junction p/n device. Similarly, FIG. 5 combines three p/i/n devices 100 of FIG. 3G for the fabrication of device 300. The Group IV semiconductor nanoparticles for the p/n configuration are crystalline in nature, while the Group IV semiconductor nanoparticles for the p/i/n configuration are amorphous or crystalline, or combinations thereof. In this regard, embodiments of tandem structures take advantage of the stability and efficiency of crystalline Group IV semiconductor materials, and the higher absorptivity in the visible region of the electromagnetic spectrum of amorphous Group IV semiconductor materials.

In one embodiment of device 300 of FIG. 5, n-doped layer 344, intrinsic layer 354, and p-doped layer 364 are composed of amorphous silicon carbide semiconductor materials. This may be achieved by a combination of using silicon or silicon carbide nanoparticles, and mixtures thereof in conjunction with depositing silicon carbide in the interstitial spaces of a porous compact during fabrication, or in a semiconductor thin film subsequent to fabrication, by using a precursor gas mixture of silane and methane. For the n-doped layer 342, the intrinsic layer 352, and the p-doped layer 362 of an embodiment utilizing silicon carbide semiconductor materials in the upper layers, amorphous silicon may be used. This may be achieved by using amorphous silicon nanoparticles in conjunction with depositing amorphous silicon in the interstitial spaces of a porous compact during fabrication, or in a semiconductor thin film subsequent to fabrication by using a precursor gas or gas composition of silane. Finally, in such an embodiment of device 300, the n-doped layer 340, intrinsic layer 350, and p-doped layer 360 are composed of amorphous silicon and germanium. An amorphous silicon and germanium layer may be achieved in a variety of ways. For example, but not limited by, such a layer may be achieved by using silicon nanoparticles in conjunction with a germane precursor gas or gas composition, or germanium nanoparticles, in conjunction with a silane precursor gas or gas composition, or combinations thereof.

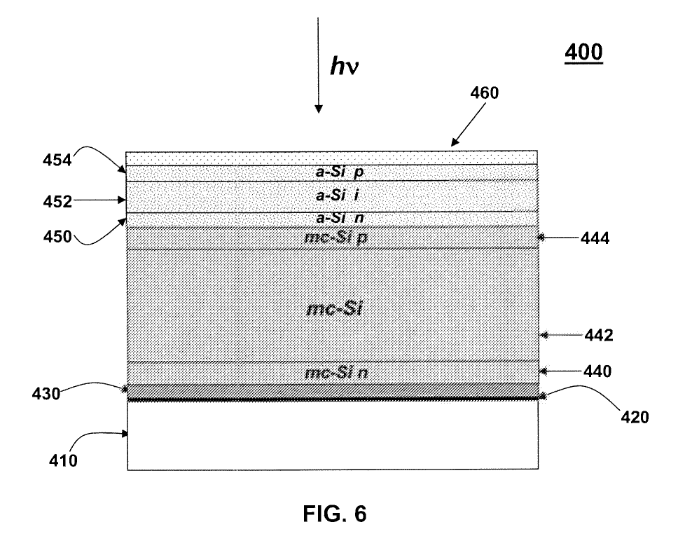

FIG. 6 depicts still another embodiment of a tandem photoconductive device 400, which takes advantage of the combined characteristics of amorphous and crystalline materials. In FIG. 6, layers 440, 442, and 444 are photoconductive n-doped, intrinsic and p-doped microcrystalline Group IV semiconductor thin films, respectively. For the intrinsic layer 542, the deposited layer of nanoparticles may be a mixture of amorphous and crystalline silicon nanoparticles. Depending on the proportion of crystalline to amorphous nanoparticles formulated in the Group IV semiconductor nanoparticle ink, as well as the processing parameters, intrinsic layer 542 may be fabricated to form embodiments of microcrystalline photoconductive intrinsic thin films. Intrinsic photoconductive layer 442 may also be formed using a silicon nanoparticle ink specifically formulated using a blend of silicon nanoparticles, and an appropriate amount of a p-doped silicon nanoparticles, so as to compensate for contaminants, such as oxygen, which may then act to create undesirable energy levels. For the doped layers (440, 444, 450, 454) of device 400, the mixture of amorphous and crystalline silicon nanoparticles used to form such layers are either doped amorphous silicon nanoparticles, or doped crystalline silicon nanoparticles or both. Alternatively, the amorphous and crystalline nanoparticle thin film is then subsequently doped using standard procedures. For the n-doped layer 440, intrinsic layer 442, and p-doped layer 444, microcrystalline thin films may result from the use of crystalline Group IV nanoparticles and amorphous Group IV semiconductor material deposited from precursor gas decomposition. The thickness of the absorbing intrinsic microcrystalline layer 442 is about 0.2 micron to about 3 microns, while the microcrystalline n-doped 440 and p-doped 444 layers that are critical for charge separation are about 10 nm to about 50 nm. In a similar fashion, the thickness of the absorbing intrinsic amorphous layer 452 is about 100 nm to about 300 nm, while the amorphous n-doped 450 and p-doped 454 layers that are critical for charge separation are about 10 nm to about 50 nm. Finally, a transparent conductive oxide (TCO) layer 460 of between about 100 nm to about 200 nm is deposited on the p-doped layer to complete the fabrication of a p/n Group IV semiconductor photoconductive device.

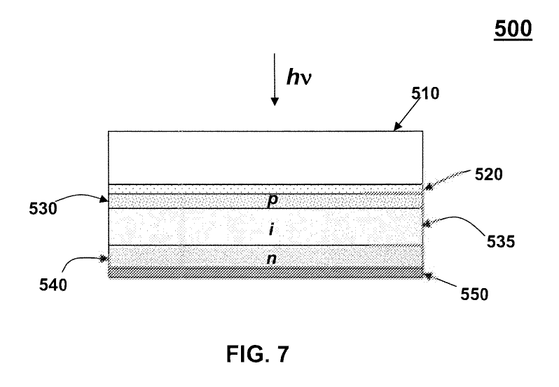

All the photoconductive thin film devices so far discussed have the substrate shown as the most distal layer upon which the electromagnetic radiation would impinge. However, one of ordinary skill in the art would recognize that devices such as those shown in FIG. 7, where the light first impinges on the substrate are also devices that may readily be fabricated using embodiments of process method 30 of FIGS. 3A-3G.

For example, in FIG. 7, an embodiment of a nanoparticle ink could be formulated using amorphous silicon nanoparticles of about 5.0 nm in diameter, blended with crystalline germanium nanoparticles of about 4.0 nm in diameter. Upon substrate 510, a TCO layer 520 of between about 100 nm to about 200 nm would be deposited. The nanoparticle ink used for the deposition of doped layers 530 and 540 of p/i/n device 500 would be formulated using amorphous silicon and crystalline germanium nanoparticles, as well as either doped amorphous silicon nanoparticles, or doped crystalline germanium nanoparticles or both. Alternatively, the thin film amorphous and crystalline nanoparticle film is then subsequently doped using standard procedures. The nanoparticle ink used for the deposition of the intrinsic layer 535 of p/i/n device 500 would be formulated using amorphous silicon and crystalline germanium nanoparticles, or also be formed using a nanoparticle ink specifically formulated using a blend of Group IV nanoparticles, and an appropriate amount of a p-doped Group IV nanoparticles, so as to compensate for contaminants, such as oxygen, which may then act to create undesirable energy levels The thickness of the photoconductive thin intrinsic film layer 535 is between about 0.2 microns to about 3.0 microns in thickness. The p-doped photoconductive layer 530 is between about 10 nm to about 100 nm in thickness, while the n-doped photoconductive layer 540 is between about 10 nm to about 100 nm in thickness. The second electrode 550 is selected from conductive materials, such as, for example, aluminum, molybdenum, chromium, titanium, nickel, and platinum, and is between about 10 nm to about 1000 nm in thickness for the various embodiments of a Group IV photoconductive, such as that shown in FIG. 7. As described for device 100 of FIG. 3G, p-doped layer 530, intrinsic layer 535, and n-doped layer 540 are all processed in an inert, substantially oxygen free environment for a selected time at a targeted temperature in the presence of a precursor gas either during fabrication from a porous compact or subsequent to densified thin film formation.

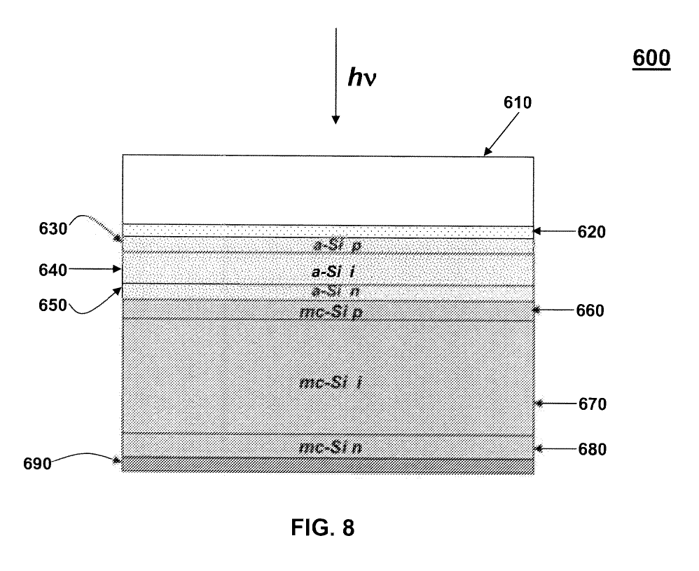

Finally, Group IV photoconductive devices of greater complexity are also possible for devices in which the light first impinges on the substrate. Shown in FIG. 8, an embodiment of such a device is shown, which is similar in structure to that of FIG. 6. The considerations of the choice of substrate and TCO are the same as for those discussed for those of device 100 of FIG. 3G. On substrate 610, a TCO layer 620 of between about 0.5 micron to about 1 micron is deposited. The thickness of the absorbing intrinsic amorphous layer 640 is about 100 nm to about 300 nm, while the amorphous p-doped 630 and n-doped 650 layers that are critical for charge separation are about 10 nm to about 50 nm. The thickness of the absorbing intrinsic microcrystalline layer 670 is about 0.2 micron to about 3 microns, while the microcrystalline p-doped 660 and n-doped 680 layers that are critical for charge separation are about 10 nm to about 50 nm. In other embodiments of device 600 of FIG. 8, the intrinsic layer 670 may be fabricated using mixtures of amorphous silicon nanoparticles and amorphous germanium nanoparticles. In still other embodiments of device 600 of FIG. 8, the intrinsic layer 670 may be fabricated using mixtures of amorphous silicon nanoparticles and crystalline germanium nanoparticles. For the p-doped layer 660, intrinsic layer 670, and n-doped layer 680, microcrystalline thin films may result from the use of crystalline Group IV nanoparticles and amorphous Group IV semiconductor material deposited from precursor gas decomposition.

Moreover, it is contemplated that combinations of types of processing can be integrated to create embodiments of Group IV photoconductive devices. For example, plasma enhanced chemical vapor deposition (PECVD) can currently deposit crystalline hydrogen terminated silicon thin films at the rate of between about 0.1 to 5 Å/s. While the quality of the quality of the crystalline material is high, the process suffers from a low film deposition rate, increasing the cost of photoconductive thin films fabricated thereby. For example, given the upper end of the intrinsic layer film thickness of 3 microns, even at the highest rate of deposition, this would require about 2 hours of PECVD processing to deposit such a layer. In contrast, the deposition of a 3 micron layer of nanoparticles, followed by fabrication to produce a Group IV photoconductive thin film layer may be about only 10% of the time. Accordingly, the combination of the PECVD process and processes disclosed herein may be used to fabricate embodiments of Group IV photoconductive devices.

For example, for embodiments of device 400 of FIG. 6 and embodiments of device 600 of FIG. 8, the p-doped and n-doped layers of these devices are for charge separation, while the intrinsic layers are for photon adsorption. In that regard, intrinsic layers 442 and 452 of device 400, and layers 640 and 670 of device 600 may be fabricated as described for device 100 of FIG. 3G. However, for n-doped layers 440 and 450, as well as p-doped layers 444 and 454 of device 400, and n-doped layers 630 and 660, as well as p-doped layers 650 and 680 of device 600, these layers could be fabricated using a PECVD process.

From what has been described herein, the utility realized in fabricating native Group IV photoconductive thin films from embodiments of Group IV semiconductor nanoparticle ink formulations includes, but is not limited by: 1.) Control over formulating inks that selectively blend the appropriate particle sizes and shapes to achieve a targeted nanoparticle pack density in a deposited thin film. 2.) Control over formulating inks that have the appropriate amount of doped nanoparticle to undoped nanoparticle in order to achieve the desired performance for a specific doped layer in a targeted device embodiment. 3.) Control over formulating inks that are appropriately adjusted with dopant levels to compensate for contaminants in order to achieve the desired performance for a specific intrinsic layer in a targeted device embodiment. 4.) Control over formulating Group IV semiconductor nanoparticle inks for adjusting the photon adsorption over a wider range of the electromagnetic spectrum. 5.) Capability to rapidly deposit multiple layers over a range of thicknesses, resulting in reduced fabrication time, as well as increase in yield through defect control.

While principles of the disclosed photoconductive Group IV semiconductor thin films, devices and methods for making such thin films and devices have been described in connection with specific embodiments, it should be understood clearly that these descriptions are made only by way of example and are not intended to limit the scope of what is disclosed. In that regard, what has been disclosed herein has been provided for the purposes of illustration and description. It is not intended to be exhaustive or to limit what is disclosed to the precise forms described. Many modifications and variations will be apparent to the practitioner skilled in the art. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

What is claimed is:

1. A method of fabricating a densified nanoparticle thin film with a set of occluded pores in a chamber, comprising:
positioning a substrate in the chamber;
depositing a nanoparticle ink, the nanoparticle ink including a set of Group IV semiconductor particles and a solvent;
heating the nanoparticle ink to a first temperature between about 30° C. and about 300° C., and for a first time period between about 5 minutes and about 60 minutes, wherein the solvent is substantially removed, and a porous compact with a set of pores is formed; and
heating the porous compact to a second temperature between about 300° C. and about 900° C., and for a second time period of between about 5 minutes and about 15 minutes, and flowing a precursor gas into the chamber at a partial pressure between about 0.1 Torr and about 50 Torr, wherein the precursor gas substantially fills the set of pores, and wherein the densified nanoparticle film with the set of occluded pores is formed.

2. The method of claim 1, wherein the set of Group IV semiconductor particles is one of n-doped semiconductor particles, p-doped semiconductor particle, and intrinsic semiconductor particles.

3. The method of claim 1, wherein the substrate is one of quartz, soda lime, and borosilicate glasses.

4. The method of claim 1, further including the step of depositing a thin barrier layer before the step of positioning a substrate in the chamber.

5. The method of claim 4, wherein the thin barrier layer is conductive.

6. The method of claim 4, wherein the thin barrier layer is a dielectric.

7. The method of claim 4, wherein the thin barrier layer is one of molybdenum, titanium, nickel, platinum, silicon nitride, and alumina.

8. The method of claim 1, wherein the substrate is one of stainless steel and a heat durable polymer.

9. The method of claim 1, wherein the precursor gas includes at least one of silane, disilane, germane, digermane, an halide analog of silane, an halide analog of disilane, an halide analog of germane, and an halide analog digermane.

10. The method of claim 1, wherein the precursor gas includes at least one of boron difluoride, trimethyl borane, diborane, phosphorous oxychloride, phosphine, and arsine.

11. A method of fabricating a densified nanoparticle thin film with a set of occluded pores in a chamber, comprising:
positioning a substrate in the chamber;
depositing a nanoparticle ink, the nanoparticle ink including a set of Group IV semiconductor particles and a solvent;
heating the nanoparticle ink to a first temperature between about 30° C. and about 300° C., and for a first time period of between about 5 minutes and about 60 minutes, and flowing a precursor gas into the chamber at a partial pressure between about 0.1 Torr and about 50 Torr, wherein the solvent is substantially removed, and a porous compact with a set of pores is formed; and wherein the precursor gas substantially fills the set of pores; and
heating the porous compact to a second temperature between about 300° C. and about 900° C., and for a second time period between about 5 minutes and about 15 minutes;
wherein the densified nanoparticle film with the set of occluded pores is formed.

12. The method of claim 11, wherein the set of Group IV semiconductor particles is one of n-doped semiconductor particles, p-doped semiconductor particle, and intrinsic semiconductor particles.

13. The method of claim 11, wherein the substrate is one of quartz, soda lime, and borosilicate glasses.

14. The method of claim 11, further including the step of depositing a thin barrier layer before the step of positioning a substrate in the chamber.

15. The method of claim 14, wherein the thin barrier layer is conductive.

16. The method of claim 14, wherein the thin barrier layer is a dielectric.

17. The method of claim 14, wherein the thin barrier layer is one of molybdenum, titanium, nickel, platinum, silicon nitride, and alumina.

18. The method of claim 11, wherein the substrate is one of stainless steel and a heat durable polymer.

19. The method of claim 11, wherein the precursor gas includes at least one of silane, disilane, germane, digermane, an halide analog of silane, an halide analog of disilane, an halide analog of germane, and an halide analog digermane.

20. The method of claim 11, wherein the precursor gas includes at least one of boron difluoride, trimethyl borane, diborane, phosphorous oxychloride, phosphine, and arsine.
